(19) United States
(12) Patent Application Publication
(10) Pub. No.: US 2022/0173729 A1
(43) Pub. Date: Jun. 2, 2022

(54) FINE DELAY CELL AND DELAY CIRCUIT HAVING THE SAME

(71) Applicant: SK hynix Inc., Gyeonggi-do (KR)

(72) Inventor: Sung Ryong LEE, Gyeonggi-do (KR)

(21) Appl. No.: 17/213,860

(22) Filed: Mar. 26, 2021

(30) Foreign Application Priority Data
Nov. 27, 2020 (KR) 10-2020-0162744

(51) Int. Cl. H03K 5/134

(52) U.S. Cl. CPC H03K 5/134; H03K 2005/00195

(57) ABSTRACT

A delay cell includes first and second delay elements coupled in series between an input terminal and an output terminal, and a switch having one terminal coupled to a common node of the first and second delay elements, and another terminal that is floating, and turned on according to a delay control signal.

### CROSS-REFERENCE TO RELATED APPLICATION

The present application claims priority to Korean Patent Application No. 10-2020-0162744, filed on Nov. 27, 2020, which is herein incorporated by reference in its entirety.

### BACKGROUND

### 1. Field

The disclosure relates to semiconductor design technology, and specifically to, a delay circuit including a plurality of fine delay cells.

### 2. Description of the Related Art

A delay circuit is generally disposed in an integrated circuit, and delays an input signal by a target delay amount to output the delayed signal as an output signal. The delay circuit is used for timing control of the integrated circuit and skew control of the output signal. The delay circuit is typically implemented using a number of delay cells connected in series to each other. The delay circuit may select a small number of delay cells from a number of delay cells and use the selected delay cells to delay the input signal by the target delay amount. The delay circuit may increase the delay amount in the input signal by increasing the number of selected delay cells.

On the other hand, the increasing speed of the integrated circuit further increases the need for micro-delay cells with a resolution at a femto-second (fs) level.

### SUMMARY

Various embodiments are directed to a delay circuit including a plurality of delay cells with a resolution at a femto-second (fs) level

According to an embodiment of the present disclosure, a delay cell includes first and second delay elements coupled in series between an input terminal and an output terminal; and a switch having one terminal coupled to a common node of the first and second delay elements, and another terminal that is floating, and turned on according to a delay control signal.

According to an embodiment of the present disclosure, a delay circuit includes a delay control circuit suitable for generating a plurality of delay control signals in response to an external control code; a plurality of delay elements coupled in series between an input terminal and an output terminal; and a plurality of switches, each switch having one terminal coupled to a corresponding common node of two adjacent delay elements among the delay elements, and another terminal that is floating, and turned on according to a corresponding delay control signal of the delay control signals.

According to an embodiment of the present disclosure, a delay circuit includes an input terminal; an output terminal; a common node; a first delay element coupled between the input terminal and the common node; a second delay element coupled between the common node and the output terminal; and a transistor including a first terminal coupled to the common node, a second terminal that is floating, and a third terminal configured to receive a delay control signal, the transistor turned on or turn off according to the delay control signal.

According to the embodiments of the present disclosure, the delay circuit may precisely control a delay time by providing a resolution at a femto-second (fs) level. Further, the delay circuit may implement a high-speed operation of an integrated circuit by supporting fine resolutions suitable for the high-speed operation.

### BRIEF DESCRIPTION OF THE DRAWINGS

FIGS. 1A and 1B are configuration diagrams illustrating a delay cell.

FIG. 2 is a configuration diagram illustrating a delay cell in accordance with an embodiment of the present invention.

FIG. 3 is an equivalent circuit diagram illustrating the delay cell of FIG. 1.

FIGS. 4A to 5B are circuit diagrams showing a capacitance of a switch of FIG. 3 according to a delay control signal.

FIG. 6 is a circuit diagram illustrating a delay circuit in accordance with an embodiment of the present invention.

### DETAILED DESCRIPTION

Various embodiments of the present disclosure are described below with reference to the accompanying drawings. The embodiments may, however, be embodied in different forms and thus should not be construed as limited to the embodiments set forth herein. Throughout the disclosure, like reference numerals refer to like parts throughout the various figures and embodiments of the present invention. It is noted that reference to “an embodiment,” “another embodiment” or the like does not necessarily mean only one embodiment, and different references to any such phrase are not necessarily to the same embodiment(s). The term “embodiments” when used herein does not necessarily refer to all embodiments.

It will be understood that, although the terms “first”, “second”, “third”, and so on may be used herein to identify various elements, these elements are not limited by these terms. These terms are used to distinguish one element from another element that otherwise have the same or similar names. Thus, a first element in one instance could also be termed a second or third element in another instance without indicating any change in the element itself.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present. Communication between two elements, whether directly or indirectly connected/coupled, may be wired or wireless, unless stated or the context indicates otherwise.

As used herein, singular forms may include the plural forms as well and vice versa, unless the context dearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

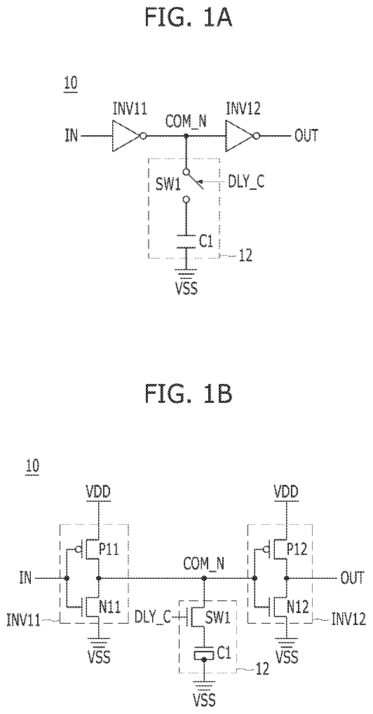

FIG. 1A is a circuit diagram illustrating a delay cell 10, and FIG. 1B is an equivalent circuit diagram illustrating the delay cell 10 of FIG. 1A.

Referring to FIG. 1A, the delay cell 10 includes a first inverter INV11, a second inverter INV12, and a delay amount adjusting circuit 12. The first and second inverters INV11 and INV12 are coupled in series between an input terminal IN and an output terminal OUT. The delay amount adjusting circuit 12 is coupled to a common node COM_N of the first and second inverters INV11 and INV12. The delay amount adjusting circuit 12 includes a switch SW1 and a capacitor C1 coupled in series between the common node COM_N and a ground voltage (VSS) terminal. The switch SW1 is turned on according to a delay control signal DLY_C, to thereby provide a capacitance of the capacitor C1 to the common node COM_N.

Referring to FIG. 1B, the first inverter INV11 includes a first P-type metal-oxide semiconductor (PMOS) transistor P11 and a first N-type metal-oxide semiconductor (NMOS) transistor N11. The PMOS transistor P11 and the NMOS transistor N11 are coupled in series between a power supply voltage (VDD) terminal and the ground voltage (VSS) terminal, and have gates commonly coupled to the input terminal IN, and drains commonly coupled to the common node COM_N. The second inverter INV12 includes a second PMOS transistor P12 and a second NMOS transistor N12, which are coupled in series between the power supply voltage (VDD) terminal and the ground voltage (VSS) terminal, and have gates commonly coupled to the common node COM_N, and drains commonly coupled to the output terminal OUT. The switch SW1 of the delay amount adjusting circuit 12 is implemented with a first metal-oxide semiconductor (MOS) transistor having a gate receiving the delay control signal DLY_C, and one terminal coupled to the common node COM_N. The capacitor C1 of the delay amount adjusting circuit 12 is implemented with a second MOS transistor having a gate coupled to another terminal of the first MOS transistor, and a source and drain commonly coupled to the ground voltage (VSS) terminal, thereby forming a MOS capacitor.

As described above, the delay cell 10 may implement an RC delay element composed of a resistor and a capacitor of a transistor. The delay cell 10 may adjust a delay amount according to the delay control signal DLY_C, and delay an input signal at the input terminal IN by the adjusted delay amount to output an output signal at the output terminal OUT. However, in order to fine adjust the delay amount, the parasitic capacitance of the switch SW1 itself and the minimum capacitance of the capacitor C1 are relatively large as compared with the capacitance of the RC delay element. Thus, it is difficult to control the input signal by the delay amount of a resolution within picoseconds (ps).

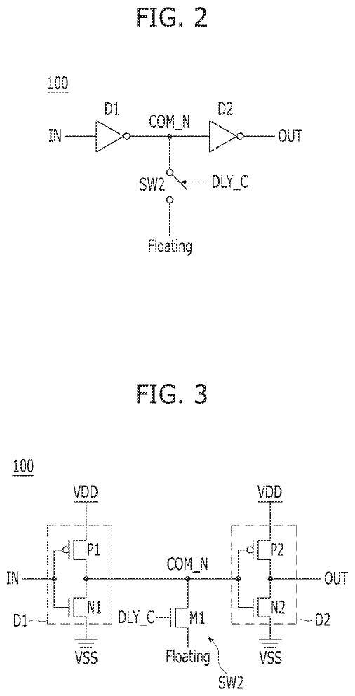

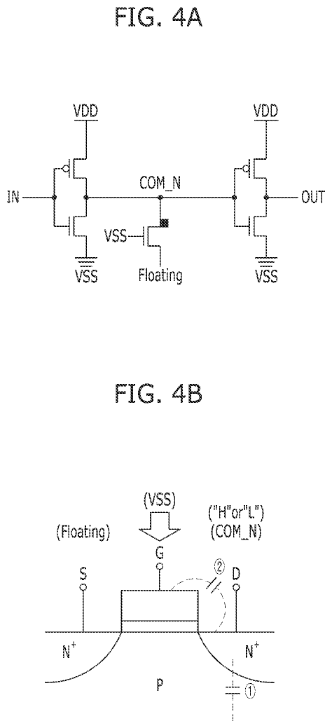

FIG. 2 is a configuration diagram illustrating a delay cell 100 in accordance with an embodiment of the present invention. FIG. 3 is an equivalent circuit diagram illustrating the delay cell 100 of FIG. 2.

Referring to FIG. 2, the delay cell 100 includes a first delay element D1, a second delay element D2, and a switch SW2. The first and second delay elements D1 and D2 may be coupled in series between an input terminal IN and an output terminal OUT. The switch SW2 may have one terminal coupled to a common node COM_N of the first and second delay elements D1 and D2, and another terminal that is floating without being connected. At this time, “floating” may mean that a certain node is not connected to another node or terminal. The switch SW2 may be turned on according to a delay control signal DLY_C. Each of the first and second delay elements D1 and D2 may be implemented with an inverter.

Referring to FIG. 3, the switch SW2 may be implemented with a MOS transistor M1 which is turned on or off according to the delay control signal DLY_C, and whose capacitance varies depending on a turned on/off state. The MOS transistor M1 may provide a first capacitance when the delay control signal DLY_C is disabled, and provide a second capacitance greater than the first capacitance when the delay control signal DLY_C is enabled. Hereinafter, it is described that the MOS transistor M1 is implemented with an NMOS transistor, as an example. However, the present invention is not limited to this, and the MOS transistor M1 may be implemented in any of an NMOS transistor and a PMOS transistor.

The first delay element D1 may include a first PMOS transistor P1 and a first NMOS transistor N1, which are coupled in series between a power supply voltage (VDD) terminal and a ground voltage (VSS) terminal, and have gates commonly coupled to the input terminal IN, and drains commonly coupled to the common node COM_N. The second delay element D2 may include a second PMOS transistor P2 and a second NMOS transistor N2, which are coupled in series between the power supply voltage (VDD) terminal and the ground voltage (VSS) terminal, and have gates commonly coupled to the common node COM_N, and drains commonly coupled to the output terminal OUT.

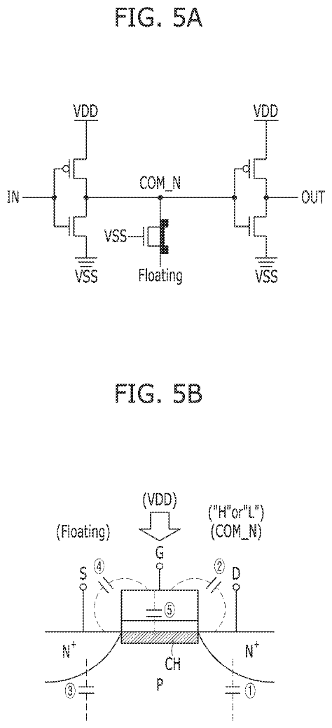

FIGS. 4A and 4B are circuit diagrams showing a capacitance of the switch SW2 of FIG. 3 when the delay control signal DLY_C is disabled to a logic low level. FIGS. 5A and 5B are circuit diagrams showing a capacitance of the switch SW2 of FIG. 3 when the delay control signal DLY_C is enabled to a logic high level.

Referring to FIG. 4A, when the delay control signal DLY_C is disabled to a logic low level (i.e., VSS), the switch SW2 is turned off. At this time, the capacitance (i.e., the first capacitance) of the switch SW2 viewed from the common node COM_N may include the parasitic capacitance such as a junction capacitance \textcircled{1} at a drain of the MOS transistor M1, and an overlap capacitance \textcircled{2} at the drain to a gate of the MOS transistor M1, as shown in FIG. 4B.

Referring to FIG. 5A, when the delay control signal DLY_C is enabled to a logic high level (i.e., VDD), the switch SW2 is turned on. As the switch SW2 is turned on, a channel CH may be formed in an area under the gate of the MOS transistor M1. At this time, the capacitance (i.e., the second capacitance) of the switch SW2 viewed from the common node COM_N may include the parasitic capacitance such as a junction capacitance \textcircled{3} of a source of the MOS transistor M1, an overlap capacitance \textcircled{4} of the source to the gate of the MOS transistor M1, and a capacitance \textcircled{5} of the gate to the channel of the MOS transistor M1, in addition to the junction capacitance \textcircled{1} at the drain of the MOS transistor M1, and the overlap capacitance \textcircled{2} at the drain to the gate of the MOS transistor M1, as shown in FIG. 5B.

As a result, the switch SW2 implemented with the MOS transistor M1 may provide the first capacitance when the delay control signal DLY_C is disabled, and provide the second capacitance greater than the first capacitance when the delay control signal DLY_C is enabled.

As described above, in accordance with the embodiment of the present invention, the delay cell 100 may delay the input signal by using the parasitic capacitance of the switch SW2 itself (i.e., the MOS transistor M1). Thus, a delay circuit including the delay cell 100 may reduce the area thereof by eliminating capacitors that were previously equipped for the delay cells. Furthermore, the delay cell 100 may adjust the delay amount only by the change in the parasitic capacitance according to the turned on/off state of the switch SW. In this case, the parasitic capacitance is present as a parasitic component, so it has a relatively small capacitance compared to the additional capacitors, which may delay the input signal with a fine delay amount of a resolution at femto-second level below 1 ps.

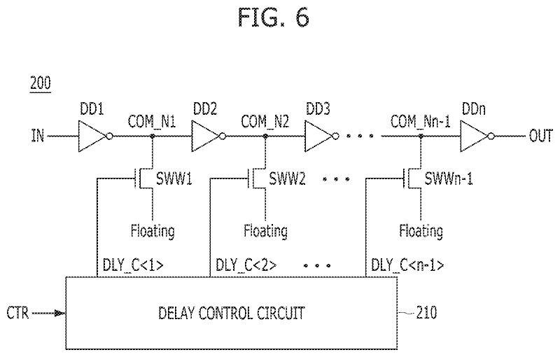

FIG. 6 is a circuit diagram illustrating a delay circuit 200 in accordance with an embodiment of the present invention.

Referring to FIG. 6, the delay circuit 200 may include a delay control circuit 210, first to n-th delay elements DD1 to DDn, and first to (n-1)-th switches SWW1 to SWWn-1.

The first to n-th delay elements DD1 to DDn may be coupled in series between an input terminal IN and an output terminal OUT. Each of the first to nth delay elements DD1 to DDn may be implemented with an inverter. Each of the first to n-th delay elements DD1 to DDn may have substantially the same configuration as the delay element of FIGS. 2 and 3.

Each of the first to (n-1)-th switches SWW1 to SWWn-1 may have one terminal coupled to a corresponding one of first to (n-1)-th common nodes COM_N1 to COM_Nn-1 of two adjacent delay elements among the first to n-th delay elements DD1 to DDn, and another terminal that is floating without being connected. Each of the first to (n-1)-th switches SWW1 to SWWn-1 may be turned on according to a corresponding one of first to (n-1)-th delay control signals DLY_C<1> to DLY_C<n-1>. In some embodiments, each of the first to (n-1)-th switches SWW1 to SWWn-1 may be implemented with a MOS transistor which is turned on or off according to the corresponding delay control signal, and whose capacitance varies depending on a turned on/off state. The MOS transistor may provide a first capacitance when the corresponding delay control signal is disabled, and provide a second capacitance greater than the first capacitance when the corresponding delay control signal is enabled. Each of the first to (n-1)-th switches SWW1 to SWWn-1 may have substantially the same configuration as the switch of FIGS. 2 to 5B. That is, the first capacitance may include the parasitic capacitance such as a junction capacitance \textcircled{1} at a drain of the MOS transistor, and an overlap capacitance \textcircled{2} at the drain to a gate of the MOS transistor, as shown in FIG. 4B. The second capacitance may include the parasitic capacitance such as a junction capacitance \textcircled{3} of a source of the MOS transistor, an overlap capacitance \textcircled{4} of the source to the gate of the MOS transistor, and a capacitance \textcircled{5} of the gate to the channel of the MOS transistor, in addition to the junction capacitance \textcircled{1} and the overlap capacitance \textcircled{2}, as shown in FIG. 5B.

The delay control circuit 210 may generate the first to (n-1)-th delay control signals DLY_C<1> to DLY_C<n-1>, in response to an external control code CTR. The first to (n-1)-th delay control signals DLY_C<1> to DLY_C<n-1> may be respectively provided to the gates of the first to (n-1)-th switches SWW1 to SWWn-1. According to an embodiment, the delay control circuit 210 may generate a thermometer code, i.e., a unary code, as the first to (n-1)-th delay control signals DLY_C<1> to DLY_C<n-1>, in response to the external control code CTR. For example, the delay control circuit 210 may generate the first to fourth delay control signals DLY_C<1:4>to have one of “0000”, “0001”, “0011”, “0111” and “1111”. Thus, when a unit delay amount D is generated by one switch, the delay control circuit 210 may control a delay amount of the delay circuit 200 to have one of an initial delay amount, the initial delay amount+D, the initial delay amount+2*D, the initial delay amount+3*D, and the initial delay amount+4*D. However, the present invention is not limited to this, and the delay control circuit 210 may generate the delay control signals in various ways. For example, the delay control circuit 210 may generate the first to fourth delay control signals DLY_C<1:4> increasing from “0000” to “1111”.

As described above, in accordance with the embodiment of the present invention, the delay circuit 200 may delay the input signal by using the parasitic capacitance of the switch itself (i.e., the MOS transistor). Thus, the delay circuit 200 may reduce the area thereof and delay the input signal with a fine delay amount of a resolution at fs level below 1 ps.

It should be noted that although the technical spirit of the disclosure has been described in connection with embodiments thereof, this is merely for description purposes and should not be interpreted as limiting. It should be appreciated by one of ordinary skill in the art that various changes may be made thereto without departing from the technical spirit of the disclosure.

For example, for the logic gates and transistors provided as examples in the above-described embodiments, different positions and types may be implemented depending on the polarity of the input signal.

The above described embodiments of the present invention are intended to illustrate and not to limit the present invention. Various alternatives and equivalents are possible. The invention is not limited by the embodiments described herein. Nor is the invention limited to any specific type of semiconductor device. Other additions, subtractions, or modifications which are apparent in view of the present disclosure are intended to fall within the scope of the appended claims.

What is claimed is:

1. A delay cell, comprising:
first and second delay elements coupled in series between an input terminal and an output terminal; and
a switch having one terminal coupled to a common node of the first and second delay elements, and another terminal that is floating, and turned on according to a delay control signal.

2. The delay cell of claim 1, wherein the switch includes:
a metal-oxide semiconductor (MOS) transistor whose capacitance varies depending on a turned on/off state according to the delay control signal.

3. The delay cell of claim 2, wherein the MOS transistor is provides a first capacitance when the delay control signal is disabled, and provides a second capacitance greater than the first capacitance when the delay control signal is enabled.

4. The delay cell of claim 3, wherein the first capacitance includes:
a junction capacitance of a drain of the MOS transistor, and
an overlap capacitance of the drain to a gate of the MOS transistor.

5. The delay cell of claim 3, wherein the second capacitance includes:
a junction capacitance of a drain of the MOS transistor,
an overlap capacitance of the drain to a gate of the MOS transistor,
a junction capacitance of a source of the MOS transistor,
an overlap capacitance of the source to the gate of the MOS transistor, and
a capacitance of the gate to a channel of the MOS transistor.

6. The delay cell of claim 1, wherein each of the first and second delay elements includes:
a P-type metal-oxide semiconductor (PMOS) transistor and an N-type metal-oxide semiconductor (MNOS) transistor, which are coupled in series between a power supply voltage terminal and a ground voltage terminal, and have gates commonly coupled to the input terminal or the common node, and drains commonly coupled to the common node or the output terminal.

7. A delay circuit, comprising:
a delay control circuit suitable for generating a plurality of delay control signals in response to an external control code;
a plurality of delay elements coupled in series between an input terminal and an output terminal; and
a plurality of switches, each switch having one terminal coupled to a corresponding common node of two adjacent delay elements among the delay elements, and another terminal that is floating, and turned on according to a corresponding delay control signal of the delay control signals.

8. The delay circuit of claim 7, wherein each of the switches includes:
a metal-oxide semiconductor (MOS) transistor whose capacitance varies depending on a turned on/off state according to the corresponding delay control signal.

9. The delay circuit of claim 8, wherein the MOS transistor provides a first capacitance when the corresponding delay control signal is disabled, and provides a second capacitance greater than the first capacitance when the corresponding delay control signal is enabled.

10. The delay circuit of claim 9, wherein the first capacitance includes:
a junction capacitance of a drain of the MOS transistor, and
an overlap capacitance of the drain to a gate of the MOS transistor.

11. The delay circuit of claim 9, wherein the second capacitance includes:
a junction capacitance of a drain of the MOS transistor,
an overlap capacitance of the drain to a gate of the MOS transistor,
a junction capacitance of a source of the MOS transistor,
an overlap capacitance of the source to the gate of the MOS transistor, and
a capacitance of the gate to a channel of the MOS transistor.

12. The delay circuit of claim 7, wherein each of the delay elements includes:
a P-type metal-oxide semiconductor (PMOS) transistor and an N-type metal-oxide semiconductor (MNOS) transistor, which are coupled in series between a power supply voltage terminal and a ground voltage terminal, and have gates commonly coupled to the input terminal or the corresponding common node, and drains commonly coupled to the corresponding common node or the output terminal.

13. The delay circuit of claim 7, wherein the delay control circuit generates a thermometer code as the delay control signals.

14. A delay circuit comprising
an input terminal;
an output terminal;
a common node;
a first delay element coupled between the input terminal and the common node;
a second delay element coupled between the common node and the output terminal; and
a transistor including a first terminal coupled to the common node, a second terminal that is floating, and a third terminal configured to receive a delay control signal, the transistor turned on or turn off according to the delay control signal.
